(19) United States
(12) Patent Application Publication
(10) Pub. No.: US 2024/0253135 A1
(43) Pub. Date: Aug. 1, 2024

(54) PARTIAL DISMANTLING DEVICE OF PHOTOVOLTAIC MODULE

(71) Applicant: KOREA INSTITUTE OF ENERGY RESEARCH, Daejeon (KR)

(72) Inventors: Jin-seok Lee, Sejong-si (KR); Gi-hwan Kang, Sejong-si (KR); Young-soo Ahn, Daejeon (KR)

(73) Assignee: KOREA INSTITUTE OF ENERGY RESEARCH, Daejeon (KR)

(21) Appl. No.: 18/120,012

(22) Filed: Mar. 10, 2023

(30) Foreign Application Priority Data
Jan. 26, 2023 (KR) 10-2023-0009956
Jan. 26, 2023 (KR) 10-2023-0009957

(51) Int. Cl. B23C 5/10; H01L 31/048; H01L 31/18

(52) U.S. Cl. CPC B23C 5/10; H01L 31/0488; H01L 31/18

(57) ABSTRACT

According to an embodiment of the invention, there is provided a partial dismantling device of a photovoltaic module, including: a worktable on which the photovoltaic module is loaded and which has a first transport unit that transports the loaded photovoltaic module; a first cutting unit, having a plurality of first cutters spaced apart from each other, that cuts a part of the photovoltaic module through a relative movement with respect to the photovoltaic module loaded on the worktable; and a second cutting unit, having a plurality of second cutters spaced apart from each other, that is disposed at the rear of the first cutting unit and cuts other parts of the photovoltaic module transported rearward without being cut by the first cutting unit.

### BACKGROUND OF THE INVENTION

### Field of the Invention

The present invention relates to a device, and more specifically to a partial dismantling device of a photovoltaic module.

### Description of the Related Art

A photovoltaic cell that is a basic unit of a crystalline photovoltaic module is a fragile element. Consequently, photovoltaic cells are generally modularized in a robust aluminum frame so as to be protected from an external impact or bad weather. The photovoltaic module is represented by a product having a photovoltaic panel shape which is manufactured by laminating element layers such as tempered glass, a filling material, photovoltaic cells, a filling material, and a back sheet, and then coupling to a cable and a power distribution board.

A service life of the photovoltaic module that is essential to a photovoltaic power generating plant is from about 20 years to 30 years, and a disposal of discarded photovoltaic modules becomes an important issue as the service life of the photovoltaic modules in use worldwide reaches the end thereof.

The photovoltaic module including a plurality of photovoltaic cells connected in series or parallel is used as a basic unit for photovoltaic power generation. The photovoltaic modules are classified into a crystalline silicon photovoltaic battery (first generation), a thin-film type photovoltaic battery (second generation), and a third generation photovoltaic battery. Currently, crystalline photovoltaic battery made of silicon as a main material is most used in South Korea. This photovoltaic module has to be demolished due to a reason such as a decrease in efficiency as time passes. Here, collecting and recycling of valuable materials in the photovoltaic module can result in resource conservation and prevention of environmental pollution.

Since prices of materials of front glass, EVA, photovoltaic cells, a back sheet, and the like which configure the photovoltaic module are relatively high, and the materials are mostly available by import, there is an attempt on a method for collecting and recycling the photovoltaic cells and glass.

The photovoltaic module can have a structure in which configurational elements such as front glass and photovoltaic cells are bound with EVA which is a sealant and binder.

In particular, a junction box attached to a photovoltaic module and an encapsulant that configures the photovoltaic module can include valuable metal and thus can be relatively highly worth recycling.

In addition, when glass that configures the photovoltaic module can be easy to recycle when the glass is separated therefrom, and thus there is an increase in demand for equipment that can separate the glass that configures the photovoltaic module and can simultaneously crush and pulverize a sandwich including valuable metal.

Meanwhile, FIG. 1 is a view illustrating an example of a device that removes a sandwich of a photovoltaic module by using a grinding stone. Since a porous grinding stone is generally used in the related art, and heat is generated in a grinding process, the sandwich can be scorched to stick to the porous grinding stone, resulting in a problem of a reduction in material collection rate arises.

### SUMMARY OF THE INVENTION

A technical object to be achieved by the invention is to provide a partial dismantling device of a photovoltaic module which is capable of removing a sandwich of the photovoltaic module by a cutting method using a cutter so as to enable efficient removal to be performed without an additional process such as a grinding stone dressing process.

In addition, another technical object to be achieved by the invention is to provide a partial dismantling device of a photovoltaic module which is capable of effectively removing a sandwich at an edge or a back surface member.

In addition, still another object to be achieved by the invention is to provide a partial dismantling device of a photovoltaic module which is capable of inhibiting a pulverized particle suctioning nozzle from being clogged with pulverized particles produced in a photovoltaic module pulverizing process, pressurizing and fixing the photovoltaic module by using a cutting module without an additional pressing plate, and inhibiting a cutting force and cutting efficiency from being decreased by a cutter being damaged by colliding with a front surface member made of tempered glass included in the photovoltaic module.

Technical objects to be achieved by the invention are not limited to the technical objects mentioned above, and the following description enables other unmentioned technical objects to be clearly understood by a person of ordinary skill in the art to which the invention pertains.

In order to achieve the technical object, an embodiment of the invention provides a partial dismantling device of a photovoltaic module, including: a worktable on which the photovoltaic module is loaded and which has a first transport unit that transports the loaded photovoltaic module; a first cutting unit, having a plurality of first cutters spaced apart from each other, that cuts a part of the photovoltaic module through a relative movement with respect to the photovoltaic module loaded on the worktable; and a second cutting unit, having a plurality of second cutters spaced apart from each other, that is disposed at the rear of the first cutting unit and cuts other parts of the photovoltaic module transported rearward without being cut by the first cutting unit.

According to the embodiment of the invention, the photovoltaic module may have a back surface member facing a front surface member and a photovoltaic cell layer interposed between the front surface member and the back surface member, and the first cutting unit and the second cutting unit may cut a sandwich including the photovoltaic cell layer and the back surface member.

According to the embodiment of the invention, the first transport unit may have a pair of rollers disposed facing each other, a conveyor connected rotatably to the pair of rollers, and a support disposed between the pair of rollers so as to support the conveyor.

According to the embodiment of the invention, the first transport unit may transport the photovoltaic module toward the first cutting unit, and the first cutting unit and the second cutting unit, in a state where positions are fixed, may cut respective parts of the photovoltaic module approaching by the first transport unit.

According to the embodiment of the invention, the partial dismantling device of a photovoltaic module may further include a second transport unit that is disposed at above the worktable so as to face the first transport unit and moves the photovoltaic module in the same direction as the first transport unit, and the photovoltaic module may pass between the first transport unit and the second transport unit in a state of being pressurized by the first transport unit and the second transport unit during a cutting process.

According to the embodiment of the invention, before positions of the first cutting unit and the second cutting unit are fixed, heights of the first cutting unit and the second cutting unit or a height of the worktable may be adjusted based on a location of the photovoltaic module loaded on the worktable.

According to the embodiment of the invention, the partial dismantling device of a photovoltaic module may further include a suction unit that suctions particles of the photovoltaic module cut by the first cutting unit and the second cutting unit.

According to the embodiment of the invention, the partial dismantling device of a photovoltaic module may further include a guide unit that is disposed in front of the first cutting unit and the second cutting unit with at least a part of the guide portion protruding toward a lower end of the first cutting unit or the second cutting unit, such that the photovoltaic module is inhibited from colliding with the first cutting unit and the second cutting unit during a relative movement with respect to the first cutting unit and the second cutting unit.

According to the embodiment of the invention, the guide unit may be inclined toward the first cutting unit or the second cutting unit from a front side of the guide unit.

According to the embodiment of the invention, the guide unit may have multiple fine holes through which a cooling fluid is sprayed toward the first cutting unit or the second cutting unit.

According to the embodiment of the invention, the first cutting unit and the second cutting unit may have respective rotational axes which are perpendicular to a surface of the photovoltaic module.

According to the embodiment of the invention, the first cutting unit and the second cutting unit may be spaced apart from each other by 15 mm or more.

In order to achieve the technical object, another embodiment of the invention provides a partial dismantling device of a photovoltaic module for dismantling the photovoltaic module having a front surface member, a back surface member facing the front surface member, and a photovoltaic cell layer interposed between the front surface member and the back surface member, the partial dismantling device of a photovoltaic module including: a worktable on which the photovoltaic module is loaded and which has a first transport unit that transports the loaded photovoltaic module; a first cutting unit, having a plurality of first cutters spaced apart from each other, that cuts a part of the back surface member through a relative movement with respect to the photovoltaic module loaded on the worktable; a second cutting unit, having a plurality of second cutters spaced apart from each other, that is disposed at the rear of the first cutting unit and cuts other parts of the back surface member transported rearward without being cut by the first cutting unit; and a guide unit that is disposed in front of the first cutting unit and the second cutting unit with at least a part of the guide portion protruding a lower end of the first cutting unit or the second cutting unit, such that the photovoltaic module is inhibited from colliding with the first cutting unit and the second cutting unit during a relative movement with respect to the first cutting unit and the second cutting unit.

### BRIEF DESCRIPTION OF THE DRAWINGS

FIG. 1 is a view illustrating an example of a device that removes a sandwich of a photovoltaic module by using a grinding stone;

FIG. 2 is a perspective view illustrating a partial dismantling device of a photovoltaic module according to an embodiment of the invention;

FIG. 3 is a plan view illustrating the partial dismantling device of a photovoltaic module in FIG. 2 viewed from above;

(a) of FIG. 4 is a side view schematically illustrating a transport unit according to the embodiment of the invention, and (b) of FIG. 4 is a side view schematically illustrating a transport unit according to another embodiment of the invention;

FIG. 5 is a view for illustrating an example of a cutting unit of the partial dismantling device of a photovoltaic module according to the embodiment of the invention;

(a) of FIG. 6 is a perspective view illustrating a cutting module according to the embodiment of the invention, and (b) of FIG. 6 is a perspective view illustrating the cutting module in (a) of FIG. 6 viewed from below;

FIG. 7 is a perspective view schematically illustrating a photovoltaic module moving toward a pair of cutting modules according to the embodiment of the invention;

FIG. 8 is a side view illustrating an example of a partial peeling process of a photovoltaic module performed by the partial dismantling device of a photovoltaic module according to the embodiment of the invention; and

FIG. 9 is a view illustrating a partial dismantling device of a photovoltaic module according to still another embodiment of the invention.

### DETAILED DESCRIPTION OF THE PREFERRED EMBODIMENTS

Hereinafter, the invention will be described with reference to the accompanying drawings.

However, the invention can be realized as various different examples and thus is not limited to embodiments to be described here. Further, a part unrelated to the description is omitted from the drawings in order to clearly describe the invention, and similar reference signs are assigned to similar parts through the entire specification.

In the entire specification, when a certain part is “connected to (access, in contact with, or coupled to)” another part, this includes not only a case where the parts are “directly connected” to each other, but also a case where the parts are “indirectly connected” to each other with another member interposed therebetween. In addition, when a certain part “comprises” a certain configurational element, this means that another configurational element is not excluded but the configurational element can be further included unless specifically described otherwise.

Terms used in this specification are only used to describe a specific embodiment and are not intentionally used to limit the invention thereto. A singular form of a noun includes a plural meaning of the noun, unless obviously implied otherwise in context. In this specification, it should be understood that terms such as “include” or “have” are intended to designate the presence of features, numbers, steps, operations, components, parts, or combinations thereof described in the specification but not to preclude the presence or addition of one or more other features, numbers, steps, operations, components, parts, or combinations thereof.

Hereinafter, the embodiments of the invention will be described in detail with reference to the accompanying drawings.

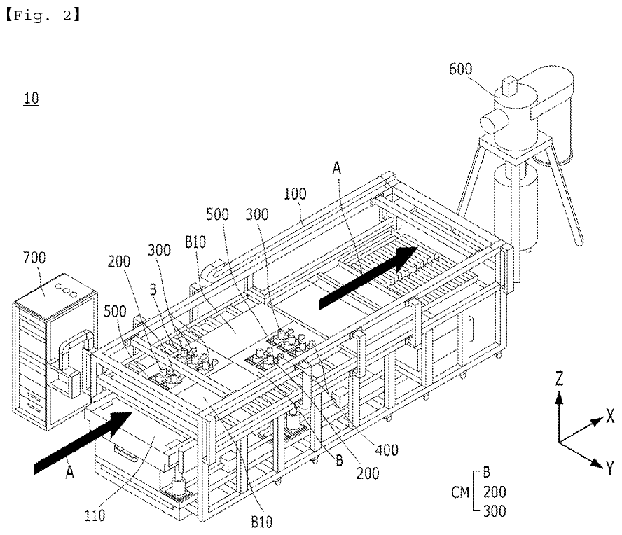

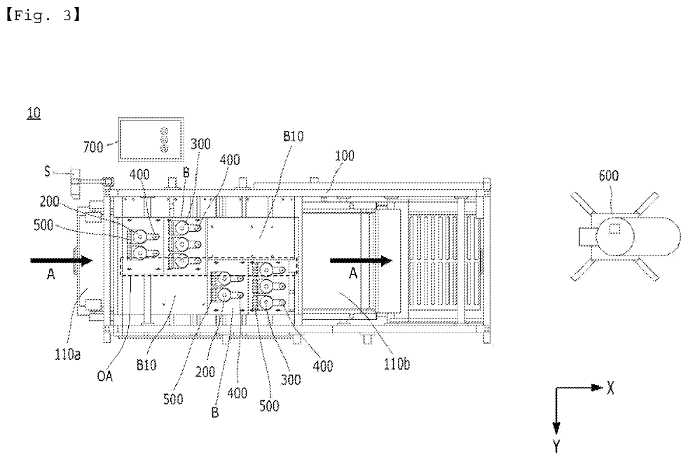

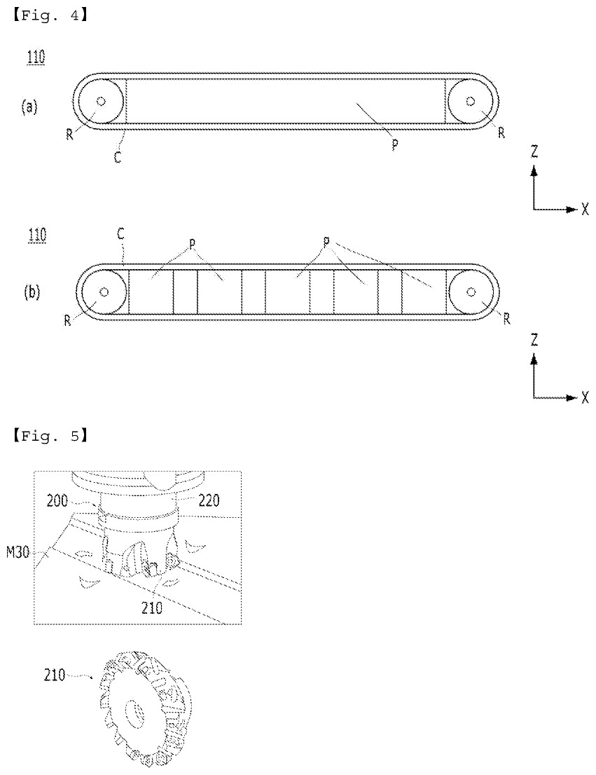

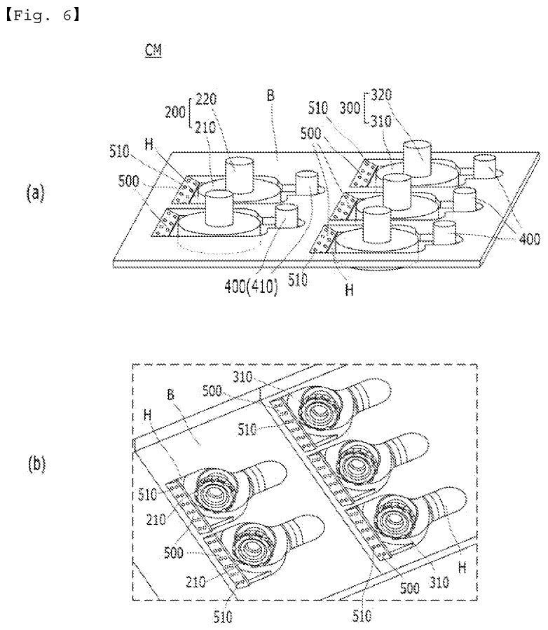

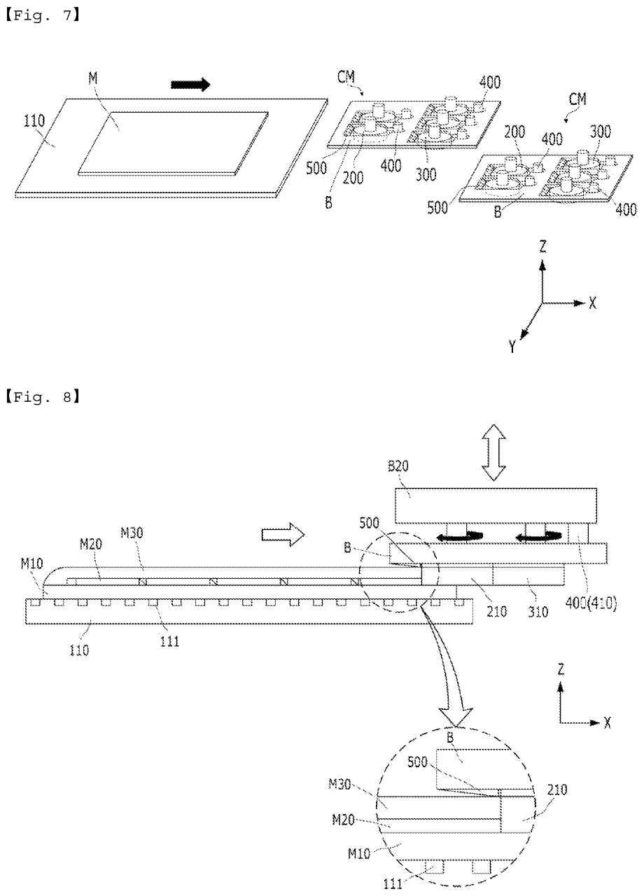

FIG. 2 is a perspective view illustrating a partial dismantling device of a photovoltaic module according to an embodiment of the invention. FIG. 3 is a plan view illustrating the partial dismantling device of a photovoltaic module in FIG. 2 viewed from above. (a) of FIG. 4 is a side view schematically illustrating a transport unit according embodiment of the invention, and (b) of FIG. 4 is a side view schematically illustrating a transport unit according to another embodiment of the invention. FIG. 5 is a view for illustrating an example of a cutting unit of the partial dismantling device of a photovoltaic module according to the embodiment of the invention. (a) of FIG. 6 is a perspective view illustrating a cutting module according to the embodiment of the invention, and (b) of FIG. 6 is a perspective view illustrating the cutting module in (a) of FIG. 6 viewed from below. FIG. 7 is a perspective view schematically illustrating a photovoltaic module moving toward a pair of cutting modules according to the embodiment of the invention. FIG. 8 is a side view illustrating an example of a partial peeling process of a photovoltaic module performed by the partial dismantling device of a photovoltaic module according to the embodiment of the invention.

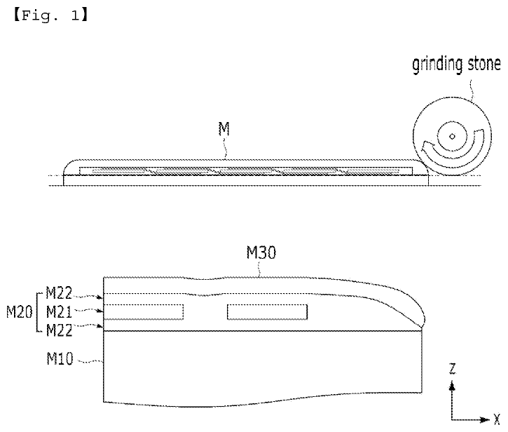

With reference to FIGS. 1 to 8, a partial dismantling device 10 of a photovoltaic module can be a device that dismantles a part of a photovoltaic module M in a recycling process of the photovoltaic module M. For example, the partial dismantling device 10 of a photovoltaic module can be used to partially peel the photovoltaic module M having a front surface member M10 and a sandwich (M20 and M30) as the remaining part of the photovoltaic module.

Here, various types of photovoltaic modules can be used as the photovoltaic module M that is partially peeled by the partial dismantling device 10 of a photovoltaic module. For example, the photovoltaic module can M include the front surface member M10, a photovoltaic cell layer M20 formed on the front surface member M10, and a back surface member M30 formed on the photovoltaic cell layer M20. In this case, the front surface member M10 can be made of tempered glass but is not limited thereto.

The back surface member M30 can be a member referred to as the above-described back sheet. Further, the photovoltaic cell layer M20 can include EVA as a type of binder and a plurality of photovoltaic cells M21 which is interposed and sealed between the front surface member M10 and the back surface member M30 by the EVA. The partial dismantling device 10 of a photovoltaic module according to the embodiment of the invention can be applied to another type of photovoltaic cell different from the above-described type of photovoltaic cell. Meanwhile, in general, the photovoltaic cell layer M20 and the back surface member M30 are collectively referred to as a sandwich, and the term, the sandwich M20 and M30 described in this specification, is to be construed as the same meaning.

In a recycling process of a photovoltaic module, examples of elements that are actually recycled generally include an aluminum frame, tempered glass, a material in a photovoltaic cell M21, a copper wire connected to the photovoltaic cell M21, and the like. Consequently, compared to another process of breaking a whole module to pieces and then classifying by material in the recycling process of the photovoltaic module M, the partial dismantling device 10 of a photovoltaic module according to the embodiment of the invention enables the front surface member M10 to be separated from the sandwich M20 and M30 so as to be recycled, thus enabling a process to be more efficiently performed.

The partial dismantling device 10 of a photovoltaic module can be a device that peels the sandwich M20 and M30 or the back surface member M30 from the photovoltaic module M described above. Here, the partial dismantling device 10 of a photovoltaic module can include a worktable 100, a first cutting unit 200, a second cutting unit 300, and a guide unit 500. In addition, the partial dismantling device 10 of a photovoltaic module can further include a suction unit 400, a dust collecting unit 600, and a control unit 700.

The photovoltaic module M can be loaded on the worktable 100. The worktable 100 can be a part at which other configurational elements of the partial dismantling device 10 of a photovoltaic module are installed, and the worktable 100 can be disposed on an external object, an inside wall of a building, the ground, or the like. The worktable 100 can be formed into various shapes and can be a structure formed by connecting multiple frames and plates, for example.

As one embodiment, the worktable 100 can transport the photovoltaic module M in one direction (or transport direction) A (or in an X-axis direction). Here, the worktable 100 can have a first transport unit 110. The first transport unit 110 can extend from one end portion (hereinafter, supply end portion) 110a to the other end (hereinafter, discharge end portion) 110b in opposite to the one end portion of the worktable 100. In this case, the photovoltaic module M can be transported by the first transport unit 110 toward the first cutting unit 200 and the second cutting unit 300 in a transport direction A in a state of being loaded on the worktable 100.

The first transport unit 110 can be configured to have at least two rollers R disposed symmetrically to and spaced apart from each other and a conveyor C connected to the two rollers R so as to be rotatably driven. Here, an outer surface of the conveyor C, on which the photovoltaic module M is placed, can be made of an elastic material so as to stably support an undersurface of the uneven front surface member M10 of the broken photovoltaic module M.

A support P for supporting the conveyor C can be disposed inside the first transport unit 110. For example, the support P can be a single long rectangular plate having a height equal or approximate to a diameter of the roller R and a length equal or approximate to a separation distance between the two rollers R. The single plate-shaped support P can be disposed between the two rollers R and can support the conveyor C. As another example, multiple supports P having a height equal or approximate to the diameter of the roller R and a length shorter than the separation distance between the two rollers R can be provided. The multiple supports P can be spaced apart at predetermined intervals between the two rollers R and can support the conveyor C.

In this manner, the single support P or the multiple supports P are disposed between the rollers R and support the conveyor C, and thereby the conveyor C can be inhibited from being slack downward due to a load of the conveyor C itself or pressure applied to the photovoltaic module M by the cutting units 200 and 300 during a cutting process.

The first transport unit 110 can have a fixing element 111 for fixing the photovoltaic module M loaded on the worktable 100. As one embodiment, the fixing element 111 can be a vacuum chuck that is provided at the conveyor C and sucks and fixes the photovoltaic module M. As another embodiment, the fixing element 111 can be a vise-shaped fixing device (not illustrated) that pressurizes and fixes the photovoltaic module M. However, the invention is not limited thereto, and any fixing device having any other shape which can fix the photovoltaic module M can be employed as the fixing element 111 without question.

In addition, the first transport unit 110 can further have a foreign matter removing element (not illustrated). Foreign matters such as cut chips or by-products produced in the cutting process of the photovoltaic module M can be attached to or caught in the conveyor C. The foreign matter removing element can be disposed at a rear end or a lower end portion of a cutting module CM and can remove a foreign matter from the conveyor C. For example, the foreign matter removing element can be a brush that rotates in a direction opposite to a rotation direction of the conveyor C. A plurality of foreign matter removing elements can be spaced apart at predetermined intervals (such as about 200 mm) at a lower end portion of the first transport unit 110, thereby improving the foreign matter removing effect.

Meanwhile, as another embodiment, the first transport unit 110 can transport the photovoltaic module M by being configured of a 3D transport device such as a robotic arm that can be driven in frontward, rearward, rightward, leftward, upward, downward, and rotational directions, instead of the conveyor-shaped transport method.

A height of the worktable 100 described above can be adjusted in an up-down direction (Z-axis direction). More specifically, the height of the worktable 100 can be adjusted by lifting and lowering the worktable based on a location (or location information) of the photovoltaic module M loaded on the worktable 100. A specific method for adjusting the height of the worktable 100 is to be described below.

The cutting module CM can cut the photovoltaic module M through a relative movement with respect to the photovoltaic module M loaded on the worktable 100. Here, the cutting module CM can include the first cutting unit 200, the second cutting unit 300, and a base B. In this case, the first cutting unit 200 and the second cutting unit 300 can be disposed together at a single base B.

The first cutting unit 200 can cut a part of the photovoltaic module M loaded on the worktable 100 through a relative movement with respect to the photovoltaic module M. As illustrated in FIG. 5, the first cutting unit 200 can be a vertical cutting unit. However, the invention is not limited thereto, and the first cutting unit 200 can be a horizontal cutting unit; however, the following description focuses on an embodiment of the vertical cutting unit for convenience of the description. Here, the first cutting unit 200 can have a first cutter 210 and a first connection member 220.

The first cutter 210 can cut a part of the photovoltaic module M loaded on the worktable 100. Here, the part of the photovoltaic module M cut by the first cutter 210 can be the sandwich M20 and M30 including the photovoltaic cell layer M20 and the back surface member M30.

As one embodiment, the first cutter 210 can be a milling cutter. More specifically, various types of milling cutters such as a slab mill, a hollow mill, or an end mill can be employed as the first cutter 210, and the first cutter 210 can desirably cut a part of the photovoltaic module M by using a face milling method. In this manner, when the first cutter 210 is configured of a milling cutter and is operated using the face milling method, a milling cutter including a plurality of cutting blades rotates and each of the cutter blades discharge respective chips in a cutting process of the sandwich M20 and M30, thereby a high processing efficiency can be achieved.

The first connection member 220 can be connected to the first cutter 210 and can transmit driving power generated by a cutter driving unit (not illustrated) to the first cutter 210. In this case, while the photovoltaic module M is transported to the rotating milling cutter 210, the sandwich M20 and M30 at the top of the photovoltaic module M can be cut and removed.

The first cutting unit 200 can have a plurality of first cutters 210. In this case, the plurality of first cutters 210 can be disposed in a row in a width direction (such as Y-axis direction) of the photovoltaic module M.

The plurality of first cutters 210 can be spaced apart at predetermined intervals in the width direction (Y-axis direction) so as not to interfere with rotation of each other. More specifically, the plurality of first cutters 210 can be spaced apart at the predetermined intervals in the width direction (Y-axis direction) of the photovoltaic module M or the base B. Hence, separation spaces (hereinafter, first separation spaces) can be provided between the plurality of first cutters 210. Here, the first cutters 210 can be spaced apart at equal or approximate intervals to each other; however, as another embodiment, the first cutters 210 can be spaced apart at different intervals from each other.

For example, as illustrated in FIG. 6, the first cutters 210 can be provided in two. In this case, the two first cutters 210 can be disposed in a row in a state of being spaced apart from each other in the width direction (Y-axis direction) of the photovoltaic module M. Hence, the first separation space can be provided between the two first cutters 210.

The second cutting unit 300 can cut other parts of the photovoltaic module M loaded on the worktable 100 through a relative movement with respect to the photovoltaic module M. As one example, similarly to the first cutting unit 200, the second cutting unit 300 can be a vertical cutting unit and can have a second cutter 310 and a second connection member 320. Here, the second cutting unit 300 can be disposed at the rear of the first cutting unit 200 based on a moving direction (X-axis direction) of the photovoltaic module M.

The second cutter 310 can cut parts other than the above-described part of the photovoltaic module M. The other parts of the photovoltaic module M cut by the second cutter 310 can be the remaining part of the sandwich M20 and M30 transported rearward through the separation spaces between the plurality of first cutters 210 without being cut by the first cutting unit 200. Here, the second cutter 310 can be the same milling cutter as the first cutter 210 and can cut the other parts of the photovoltaic module M by using the face milling method.

The second connection member 320 can be connected to the second cutter 310 and can transmit driving power generated by a cutter driving unit (not illustrated) to the second cutter 310. In this case, while the photovoltaic module M is transported to the second cutter 310 as the rotating milling cutter, the sandwich M20 and M30 at the top of the photovoltaic module M can be cut and removed.

A plurality of second cutters 310 can be provided. In this case, the plurality of second cutters 310 can be disposed at the rear of the first cutting unit 200 in a row in a width direction (Y-axis direction) of the photovoltaic module M. More specifically, the second cutters 310 can be disposed one by one at the rear of spaces between the plurality of first cutters 210.

The plurality of second cutters 310 can be spaced apart at predetermined intervals in the width direction (Y-axis direction) so as not to interfere with rotation of each other. More specifically, the plurality of second cutters 310 can be spaced apart at the predetermined intervals in the width direction (Y-axis direction) of the photovoltaic module M or the base B. Hence, separation spaces (hereinafter, second separation spaces) can be provided between the plurality of second cutters 310. Here, the second cutters 310 can be spaced apart at equal or approximate intervals. However, as another embodiment, similarly to the first cutters 210 described above, the second cutters 310 can be spaced apart at different intervals from each other.

As illustrated in FIG. 6, when the first cutters 210 is provided in two, the second cutters 310 can be provided in three and disposed at the rear of the two first cutters 210. In this case, one second cutter 310 can be disposed between the two first cutters 210, and the remaining two second cutters 310 can be disposed on both outer sides of the first cutters 210, respectively. Here, the three second cutters 310 can be disposed in a row in a state of being spaced apart from each other in the width direction (Y-axis direction) of the photovoltaic module M. Hence, the second separation spaces can be provided respectively between the three second cutters 310.

However, the above-provided description corresponds to one embodiment of the invention, and, as another embodiment, the number of the first cutters 210 can be greater than the number of second cutters 310, or the number of cutters 210 or 310 can be different from the number described above.

In this manner, separation between the cutters 210 or 310 at predetermined intervals can inhibit a phenomenon in which an organic substance in the photovoltaic sticks to the cutters with frictional heat or damage to a cutter by collision between the cutters due to disposition of the cutters 210 or 310 being too close and frictional heat being focused between the cutters 210 or 310.

Meanwhile, the moving direction A of the photovoltaic module M can be perpendicular to rotational axes of the first cutting unit 200 and the second cutting unit 300. Further, the first cutters 210 and the second cutters 310 can be disposed to be spaced apart from each other at preset intervals. For example, the preset interval can be 15 mm or more, and the spaced-apart disposition of the cutters 210 or 310 as described above can inhibit cut by-products from being caught between the cutter blades and further inhibit a problem of molten and sticking pulverized particles caught between the cutter blades due to the frictional heat.

The first cutting unit 200 and the second cutting unit 300 described above can be disposed at a single base B. Here, the base B can be disposed at the worktable 100. More specifically, the base B can be disposed at an upper side of the worktable 100 from the first transport unit 110, and thus a top surface of the first transport unit 110 and an undersurface of the base B can be spaced apart from each other.

The base B can be formed into various shapes and can be a thin rectangular plate, for example. The base B can have multiple through-holes H into which the plurality of first cutters 210 and the plurality of second cutters 310 are inserted.

The multiple through-holes H can be arranged at the base B so as to correspond to positions of the first cutters 210 and the second cutters 310. As on embodiment, of the multiple through-holes H, two through-holes H (hereinafter, front through-holes) can be disposed at a front side of the base B, and three through-holes H (hereinafter, rear through-holes) can be disposed at the rear of the front through-holes H, based on the moving direction (X-axis direction) of the photovoltaic module M. In this case, the first cutters 210 can be inserted into the front through-holes H, respectively, and the second cutters 310 can be inserted into the rear through-holes H, respectively.

In this case, the cutters 210 and 310 can protrude downward from the undersurface of the base B so as to perform a cutting process on the photovoltaic module M. As one embodiment, when the sandwich M20 and M30 is cut from the photovoltaic module M, a protruding distance of the cutters 210 and 310 can be equal to or longer than a thickness of the sandwich M20 and M30 and can be 1 mm or longer, for example. On the other hand, as another embodiment, when only the back surface member M30 is cut from the photovoltaic module M, a protruding distance of the cutters 210 and 310 can be equal to or longer than a thickness of the b surface member M30 and can be shorter than the thickness of the sandwich M20 and M30.

Here, the base B can have a second transport unit B10. The second transport unit B10 can move the photovoltaic module M in the same direction as the first transport unit 110 can, while cutting is performed. Here, the second transport unit B10 can be a conveyor (not illustrated), for example. The second transport unit B10 can be disposed at the base B so as to be positioned above the first transport unit 110. Here, the second transport unit B10 can be disposed above a side of the supply end portion 110a of the first transport unit 110 and can face the top surface of the first transport unit 110 in a state of being spaced apart from the first transport unit 110.

As one embodiment, the second transport unit B10 can be disposed at one side of the cutting module. More specifically, the second transport unit B10 can be disposed at one side of the base B and can extend in parallel with a longitudinal direction (X-axis direction) of the base B or the transport direction A. Here, the second transport unit B10 can have a length equal or approximate to a length of the base B.

As another embodiment, the second transport unit B10 can be disposed at a center of the base B. Here, a plurality of second transport units B10 can be provided. The plurality of second transport units B10 can be disposed between the first cutters 210 and between the second cutters 310. More specifically, some of the plurality of second transport units B10 can be disposed at the first separation spaces between the first cutters 210, respectively, and the other units of the plurality of second transport units B10 can be disposed at the second separation spaces between the second cutters 310, respectively. Here, the second transport unit B10 can extend in the transport direction A at the separation space and the second separation space and can have a length equal or approximate to a length of the through-hole H.

For example, in a case of the cutting module CM illustrated in FIG. 6, the second transport unit B10 can be disposed at the first separation space between the two first cutters 210. Further, the second transport units B10 can be disposed between the three second cutters 310, respectively. In addition, optionally, the second transport units B10 be further disposed at both respective outer sides of the two second cutters 310 disposed at the outermost sides based on the width direction (Y-axis direction). Here, the second transport units B10 can be further disposed at both respective outer sides of the two first cutters 210 based on the width direction (Y-axis direction), without question.

The second transport units B10 according to the embodiments described above are provided, and thereby the photovoltaic module M loaded on the worktable 100 can meet the second transport units B10 disposed above the first transport unit as the photovoltaic module M is moved toward the supply end portion 110a of the first transport unit 110. Here, the photovoltaic module M is transported by the first transport unit 110 and the second transport units B10 which rotate in the same direction in a state of being caught between the transport units 110 and B10, and thereby the photovoltaic module M can move past the first cutting unit 200 and the second cutting unit 300.

In this manner, the photovoltaic module M can move past the cutting units 200 and 300 in a state of being pressurized in the up-down direction by the first transport unit 110 and the second transport unit B10, and thereby the photovoltaic module M can be stably pressurized and supported during the cutting process even without an additional pressing plate (or pressing bar) for pressurizing and fixing the photovoltaic module. In addition, the conveyor C is supported by the support P provided in the first transport unit 110, and thereby the conveyor C of the first transport unit 110 can endure downward pressure applied by the second transport unit B10.

As on embodiment, the base B can be connected to the worktable 100 in a fixed manner such that positions of the first cutting unit 200 and the second cutting unit 300 can be fixed. In this case, the photovoltaic module M loaded on the worktable 100 can be moved by the first transport unit 110 and the second transport unit B10 toward the first cutting unit 200 and the second cutting unit 300 in a state where positions are fixed, and the sandwich M20 and M30 can be cut.

As another embodiment, the photovoltaic module M can be loaded on the worktable 100 to be in a state where positions are fixed, and the first cutting unit 200 and the second cutting unit 300 can move toward the photovoltaic module M such that the cutting process is performed. However, the following description focuses on an embodiment in which the photovoltaic module M is moved in a state where the positions of the cutting units 200 300 are fixed.

The cutting module CM can further include a height adjusting unit B20. The height adjusting unit B20 can adjust a height of the cutting module CM by moving the cutting module CM in the up-down direction (Z-axis direction). More specifically, the height of the cutting module CM can be adjusted by the height adjusting unit B20 that lifts and lowers the cutting module based on a location (or location information) of the photovoltaic module M loaded on the worktable 100. In this manner, a lifting and lowering function of the cutting module CM can improve easiness and efficiency of cutter blade replacement work since the cutting module CM can be lifted and then a worn or damaged cutter blade can be replaced in a case where the cutter blade of the cutting units 200 and 300 has to be replaced. Meanwhile, a specific method for adjusting the height of the cutting module CM is to be described below.

A plurality of cutting modules CM described above can be provided. In this case, the plurality of cutting modules CM can be disposed in a staggered pattern in the width direction (Y-axis direction) of the photovoltaic module M (worktable 100).

As one embodiment, a pair of cutting modules CM can be provided. In this case, one of the pair of cutting modules CM can cut one part of the photovoltaic module M, and the other of the pair of cutting modules CM can cut the other part of the photovoltaic module M.

As illustrated in FIG. 3, any one cutting module (hereinafter, front cutting module) of the pair of cutting modules CM can be disposed in a front side, and the other cutting module (rear cutting module) of the pair of cutting modules CM can be disposed at a rear side based on the transport direction A. Further, the front cutting module CM and the rear cutting module CM can be disposed to face each other in a diagonal direction (hereinafter, first diagonal direction) with respect to the transport direction A. Here, a second transport unit (hereinafter, front second transport unit) B10 provided on a side of the front cutting module CM and a second transport unit (hereinafter, rear second transport unit) B10 provided on a side of the rear cutting module CM can be disposed to face each other in a diagonal direction (hereinafter, second diagonal direction) different from the above-described first diagonal direction.

More specifically, when viewed in the transport direction A, the front cutting module CM can be disposed on a front left side of the first transport unit 110 and the front second transport unit B10 can be disposed on a front right side of the first transport unit 110, such that the front cutting module CM and the front second transport unit B10 can be disposed side by side in the width direction (Y-axis direction). Here, the rear cutting module CM can be disposed on a rear right side of the first transport unit 110 and the rear second transport unit B10 can be disposed on a rear left side of the first transport unit 110, such that the rear cutting module CM and the rear second transport unit B10 can be disposed side by side in the width direction (Y-axis direction). Hence, the front cutting module CM and the rear second transport unit B10 can be disposed sequentially and side by side in the transport direction A. Further, the front second transport unit B10 and the rear cutting module CM can be disposed sequentially and side by side in the transport direction A.

In this case, the photovoltaic module M can be moved in the transport direction A in a state of being pressurized by the first transport unit 110 and the pair of second transport units B10 such that the cutting process can be performed in a manner in which one region (for example, left portion of the sandwich M20 and M30) can be cut by the front cutting module CM and then the other region (for example, right portion of the sandwich M20 and M30) can be cut by the rear cutting module CM.

Here, the sum of widths of the pair of cutting modules CM can be formed to have a sum of widths thereof larger than a width of the photovoltaic module M, and the pair of cutting modules CM can be disposed to partially overlap each other when viewed from above the device 10. Hence, the one region cut by the front cutting module CM and the other region cut by the rear cutting module CM can partially overlap each other. In this manner, the entire top surface of the photovoltaic module M can be cut without a space between the pair of cutting modules CM not being cut based on the width direction (Y-axis direction).

However, the invention is not limited thereto, and the pair of cutting modules CM can be disposed in another pattern different from the pattern in the above-described embodiment. In addition, tree or more cutting modules CM can be provided.

The suction unit 400 can suction particles of the photovoltaic module M produced in the cutting process. More specifically, the suction unit 400 can suction and remove chips or by-products produced while the photovoltaic module M is cut by the first cutting unit 200 and the second cutting unit 300.

As one embodiment, the suction unit 400 can have a suction driving element (not illustrated) that suctions air and a cylinder-shaped suction nozzle 410 that is connected to the suction driving element and suctions particles of the cut photovoltaic module M. The suction nozzle 410 can have an opened terminal portion, and the terminal portion can be disposed at the rear of the first cutting unit 200 and the second cutting unit 300. Further, the other end of the terminal portion of the suction nozzle 410 can extend to the outside of the device 10 (for example, above the device 10). In this case, particles of the photovoltaic module M cut by the cutting units 200 and 300 can be suctioned through the terminal portion of the suction nozzle 410 and then can be discharged and removed to the outside of the device 10.

A plurality of suction nozzles 410 can be provided. In this case, the plurality of suction nozzles 410 can be disposed at the rear of the first cutters 210 and the second cutters 310, respectively. Here, the terminal portions of the suction nozzles 410 can be inserted into the through-holes H of the base B into which the first cutters 210 or the second cutters 310 facing the respective suction nozzles 410 are inserted. Hence, the terminal portions of the suction nozzles 410 can suction the cut chips or by-products in a state of directly facing the top surface of the photovoltaic module M.

The guide unit 500 can guide the photovoltaic module M toward the first cutting unit 200 and the second cutting unit 300 when the photovoltaic module M loaded on the worktable 100 is moved relatively with respect to the cutting module CM. Here, the guide unit 500 can be disposed at the cutting module CM.

As one embodiment, the guide unit 500 can be disposed at the base B. Here, the guide unit 500 can be positioned in front of the first cutter 210 or in front of the second cutter 310. Hence, the guide unit 500 can be positioned opposite to the suction nozzle 410 based on the first cutter 210 or the second cutter 310.

The guide unit 500 can at least partially protrude toward a lower side of the cutting module CM. More specifically, a front end of the guide unit 500 can be connected to an inner surface of the through-hole H positioned on a front side of inner surfaces of the through-holes H. Further, a rear end of the guide unit 500 can extend toward a lower side of the base B and can be disposed to protrude toward the outside (that is, lower side) of the through-hole H. Here, a protruding length of the rear end of the guide unit 500 can be equal or approximate to protruding lengths of the cutters 210 and 310.

The guide unit 500 can be disposed in an inclined state at a predetermined angle with respect to a length direction (X-axis direction) of the base B or the transport direction A of the photovoltaic module M. In other words, the guide unit 500 can be disposed to be inclined toward a rear side (or the rear end) from a front side (or the front end). Hence, a space between the guide unit 500 and the first transport unit 110 can be narrower from the front side of the guide unit 500 toward the first cutters 210 or the second cutters 310, and thus the rear end of the guide unit 500 can be positioned at a height where the rear end is almost in contact with the top surface of the photovoltaic module M (or the back surface member M30).

When the device 10 does not include the guide unit 500 and the photovoltaic module M is moved directly to the first cutters 210, the first cutters 210 can collide with the photovoltaic module M to damage the front surface member M10 made of glass, thus the cutting process not being appropriately performed. Here, as described above, the guide unit 500 protruding downward from the base B can be disposed in front of the first cutters 210, and thus, the guide unit 500 can inhibit collision between the front end of the photovoltaic module M and the first cutters 210, thus, inhibiting the front surface member M10 from being damaged. As a result, cutting efficiency can be improved.

The guide unit 500 can partially block the through-hole H. More specifically, the guide unit 500 can have a shape corresponding to a front end portion of the through-hole H. As illustrated in FIG. 6, the front end portion of the through-hole H can have a rectangular cross-section having an area larger than that of a rear end portion. In this case, the guide unit 500 can be a plate having a rectangular cross-section corresponding to the front end portion of the through-hole H. However, the invention is not limited thereto, and the through-hole H and the guide unit 500 can have a shape different from the shape described above.

The guide unit 500 described above can be connected to the front end portion of the through-hole H and can block the front end portion of the through-hole H. The guide unit 500 can inhibit cut particles of the photovoltaic module M from gathering inside the through-hole H through the front end portion of the through-hole H.

The guide unit 500 can have multiple holes 510 (hereinafter, fine holes) having a fine size. The multiple fine holes 510 can be evenly disposed all across the entire area of the guide unit 500. The multiple fine holes 510 can be used to cool the frictional heat produced during the cutting process. More specifically, a liquid such as cutting fluid can be sprayed to the first cutting unit 200 and the second cutting unit 300 through the multiple fine holes 510 or a cooling fluid such as hydrogen, neon, nitrogen, oxygen, or air can sprayed, so as to inhibit pulverized particles from being caught between the first cutters 210 and the second cutters 310 and simultaneously cool the first cutting unit 200 and the second cutting unit 300 heated as the cutting process is performed.

A plurality of guide units 500 can be provided. The plurality of guide units 500 can be disposed in front of the plurality of first cutters 210 and the plurality of second cutters 310, one at respective position. In this case, as the photovoltaic module M is moved toward the cutting module CM, the photovoltaic module M can be moved past the guide units 500 to the first cutters 210 and the second cutters 310 positioned at the rear of the guide units 500, and the sandwich M20 and M30 can be cut.

The guide unit 500 can be spaced apart at predetermined intervals from the first cutting unit 200 and the second cutting unit 300. More specifically, when the guide unit 500 is provided in plurality, a rear end of the guide unit 500 disposed in front of the first cutters 210 can be spaced apart from the first cutters 210 by a first separation distance. Further, a rear end of the guide unit 500 disposed in front of the second cutters 310 can be spaced apart from the second cutters 310 by a second separation distance.

Here, the first separation distance and the second separation distance can be equal or approximate to each other and can be 5 mm or longer and shorter than 90 mm (hereinafter, separation range). The first separation distance and the second separation distance can be different from each other within the above-described separation range. In this manner, the separation between the guide unit 500 and the cutters 210 and 310 within the separation range can inhibit cut particles from being caught therebetween due to the guide unit 500 and the cutters 210 and 310 being too close. Further, it can inhibit the cutting module CM (or the base B) from being bent by an external force generated by being pressurized by the front end of the photovoltaic module M during the cutting process due to distance between the guide unit 500 and the cutters 210 and 310 being too long.

Meanwhile, although not illustrated in the drawings, the partial dismantling device 10 of a photovoltaic module can include an additional guide unit (not illustrated). In this case, the additional guide unit can be disposed in front of the base B. The additional guide unit can be configured to be inclined toward the front side of the base B, and a rear end of the additional guide unit can protrude more downward from the undersurface of the base B. The additional guide unit can inhibit the front surface member M10 from being damaged by colliding with the front end of the base B during relative movement with respect to the photovoltaic module M.

The dust collecting unit 600 can suction and remove dust or the like produced during a partial peeling process or the cutting process of the photovoltaic module M. More specifically, the dust collecting unit 600 can secondarily suction and remove particles cut from the photovoltaic module M and remaining without being removed by the above-described suction unit 400. As illustrated in FIG. 2, the dust collecting unit 600 can be disposed on one side of the worktable 100; however, the invention is not limited thereto.

A sensor S can acquire location information by detecting a location of the photovoltaic module M loaded on the worktable 100 from a reference point. The location information can measurement include of location information of the photovoltaic module M as necessary, such as a height of a back surface of the photovoltaic module M from a reference surface (such as the top surface of the worktable 100), a location of an edge of the photovoltaic cell layer M20 and a thickness and a location of an edge of the front surface member M10 without the photovoltaic cell layer M20, a width of the module, and the like. For example, examples of the sensor S can include a camera or an optical sensor.

As one embodiment, the sensor S can sense location information indicating information of a height from a reference point on the reference surface defined as the top surface of the worktable 100 to the front surface member M10 of the photovoltaic module M. As another embodiment, the sensor S can be realized to sense location information indicating information of a height from the reference point to at least a part of a sealant (sealant having thickness of smaller than 200 μm) on the front surface member M10. In this manner, the sensed location information can be transmitted to the control unit 700 to be described below.

The control unit 700 can control operations of the first transport unit 110, the second transport unit B10, and the height adjusting unit B20 based on the location information received from the sensor S.

More specifically, the control unit 700 can generate a first control signal by using the location information so as to adjust a height of the cutting module CM by operating the height adjusting unit B20. Here, the control unit 700 can transport and arrange the first cutting unit 200 and the second cutting unit 300 to a “set position for cutting the sandwich M20 and M30” which corresponds to a position corresponding to a thickness of the front surface member M10. Hence, the cutting units 200 and 300 can cut only the sandwich M20 and M30 on the front surface member M10 by leaving the sensed thickness of the front surface member M10.

In addition, the control unit 700 can generate a second control signal by using the location information so as to control the photovoltaic module M loaded on the worktable 100 to be moved in the transport direction A by driving the first transport unit 110 and the second transport unit B10. Hence, the cutting units 200 and 300 in a state fixed at the set positions can cut the sandwich M20 and M30 while the photovoltaic module M is moved in the transport direction A in a state of being pressurized between the first transport unit 110 and the second transport unit B10.

Meanwhile, the control unit 700 can adjust heights of the first cutting unit 200 and the second cutting unit 300 before the positions of “the first cutting unit 200 and the second cutting unit 300” (or cutting module CM) are fixed.

More specifically, the control unit 700 can control the height adjusting unit B20 to adjust the heights of the first cutting unit 200 and the second cutting unit 300 to a “cutting height” when a front edge of the photovoltaic module M enters the first cutting unit 200. Here, the cutting height can be a height at which the cutters 200 and 300 can cut the sandwich M20 and M30 or only the back surface member M30. Hence, the sandwich M20 and M30 or the back surface member M30 can be cut from the photovoltaic module M by the first cutting unit 200 and the second cutting unit 300. Then, when the sandwich M20 and M30 or the back surface member M30 of the photovoltaic module M is to be completely removed, the control unit 700 can operate the first cutting unit 200 and the second cutting unit 300 to be continuously driven in a state of staying at the cutting height.

By such process, the back surface member M30 and the photovoltaic cell layer can be removed, and a processed product remaining at the front surface member M10 (for example, tempered glass) can be formed. The processed product can be recycled.

Meanwhile, a method for partially peeling the photovoltaic module M by the partial dismantling device 10 of a photovoltaic module can be as follows.

First, the photovoltaic module M can be loaded on the worktable 100 such that the front surface member M10 of the photovoltaic module M can be sucked by a fixing element 111 such as a vacuum chuck. When the photovoltaic module M is loaded on the worktable 100, the first transport unit 110 can transport the photovoltaic module M toward the cutting module CM. Here, the cutting module CM can be in a state where position is fixed.

Next, heights of the pair of cutting modules CM can be adjusted based on a location (or location information) of the photovoltaic module M loaded on the worktable 100 before the positions of the cutting modules CM are fixed. More specifically, the first cutting unit 200 and the second cutting unit 300 provided at each of the pair of cutting modules CM can be lifted and lowered based on the location information measured by the sensor S so as to be moved to a set position at which the sandwich M20 and M30 can be cut by leaving only a portion corresponding to the thickness of the front surface member M10.

Next, the first cutting unit 200 and the second cutting unit 300 provided at the front cutting module CM that is in a fixed state can cut a region (such as a left portion) of the sandwich M20 and M30 on the front surface member M10 through the relative movement with respect to the photovoltaic module M loaded on the worktable 100 and transported in a state of being pressurized by the first transport unit 110 and the front second transport unit B10.

Then, the photovoltaic module M, from which only one region of the sandwich M20 and M30 is cut, can be moved to a rear side past the front cutting module CM. Hence, the first cutting unit 200 and the second cutting unit 300 provided at the rear cutting module CM that is in a fixed state can cut the other region (such as a right portion) of the sandwich M20 and M30 on the front surface member M10 through the relative movement with respect to the photovoltaic module M transported in a state of being pressurized by the first transport unit 110 and the rear second transport unit B10.

When the cutting is completed in this manner, the photovoltaic module M is continuously moved by the first transport unit 110 in the same direction (X-axis direction) as the transport direction, is discharged from the worktable 100, and can be stored in an external storage unit (not illustrated).

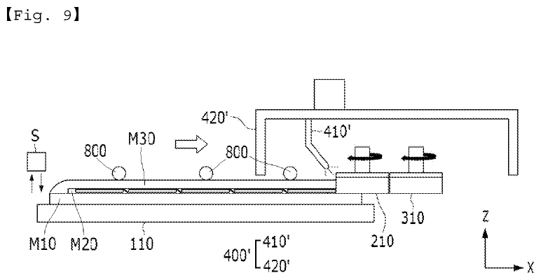

FIG. 9 is a view illustrating a partial dismantling device of a photovoltaic module according to still another embodiment of the invention.

With reference to FIG. 9, a suction unit 400′ can have a suction nozzle 410′ and a hood portion 420′. The hood portion 420′ illustrated in FIG. 9 can cover the top parts and perimeters of the cutting units 200 and 300. In this case, the suction nozzle 410′ can be disposed in an inner space partitioned by the hood portion 420′, can extend toward the cutting units 200 and 300, and can suction and remove cut chips or by-products. In this manner, the cutting process can be performed in a state where the cutting units 200 and 300 are surrounded by the hood portion 420′, and the suction nozzle 410′ can remove the chips and by-products produced in the process.

In addition, the partial dismantling device 10 of a photovoltaic module can include a support 800 that presses the photovoltaic module M. For example, the support 800 can have a shape of a pressing bar or a pressing plate which can move. As the sandwich M20 and M30 is removed by the cutting units 200 and 300, the support 800 at a corresponding location where cutting is performed can be lifted upward or can be moved to another position.

According to a more specific embodiment, when the cutting is performed, the support 800 can be moved in the same direction as the direction in which the first cutting unit 200 and the second cutting unit 300 are moved. In other words, when the photovoltaic module M is loaded on the first transport unit 110, the control unit 700 can operate the cutting units 200 and 300 and the support 800 to be moved upward and then lowered to an appropriate position based on a signal sensed by the sensor S. A lowering distance can be determined based on a height of the sandwich M20 and M30 of the photovoltaic module or a thickness of the photovoltaic module M measured by the sensor S.

The partial dismantling device 10 of a photovoltaic module according to the embodiments of the invention described above can remove the sandwich M20 and M30 of the photovoltaic module M by the cutting method using the cutters 210 and 310 and can efficiently remove the sandwich without an additional process such as a grinding stone dressing process.

In addition, the guide unit 500 that is capable of guiding the photovoltaic module M to the cutters 210 and 310 and making uneven surface of the sandwich M20 and M30 even can be disposed in front of the cutters 210 and 310, and thereby the cutting efficiency can be improved.

In addition, the photovoltaic module M can be pressurized by the two transport units 110 and B10 disposed to face each other in the up-down direction and the cutting process can be performed on the photovoltaic module M that is moved while maintaining the pressurized state, thereby being capable of peeling the sandwich M20 and M30 from the photovoltaic module M without an additional pressing plate.

The description of the invention described above is provided as an example, and a person of ordinary skill in the art to which the invention pertains can understand that it is possible to easily modify the invention to another embodiment without changing the technical idea or essential feature of the invention. Therefore, the embodiments described above are to be construed to be provided as exemplified examples in every aspect and not as examples limiting the invention. For example, the configurational elements described in singular forms can be realized in a distributed manner, and the configurational elements described in a distributed manner can be realized in a coupled manner likewise.

The scope of the invention has to be represented by the claims to be described below, and the meaning and scope of the claims and every modification or modified embodiment derived from an equivalent concept of the claims have to be construed to be included in the scope of the invention.

According to an embodiment of the invention, there can be provided a partial dismantling device of a photovoltaic module which is capable of removing a sandwich of the photovoltaic module by a cutting method with a cutter so as to enable efficient removal to be performed without an additional such as process a grinding stone dressing process.

In addition, according to another embodiment of the invention, there can be provided a partial dismantling device of a photovoltaic module which is capable of effectively removing a sandwich at an edge.

Effects of the invention are to be construed not to be limited to the above-described effects but to include any effect that can be derived from configurations of the invention described in the detailed description of the preferred embodiments and claims of the invention.

While the present invention has been described with respect to the specific embodiments, it will be apparent to those skilled in the art that various changes and modifications may be made without departing from the spirit and scope of the invention as defined in the following claims.

What is claimed is:

1. A partial dismantling device of a photovoltaic module, comprising:
a worktable on which the photovoltaic module is loaded and which has a first transport unit that transports the loaded photovoltaic module;
a first cutting unit, having a plurality of first cutters spaced apart from each other, that cuts a part of the photovoltaic module through a relative movement with respect to the photovoltaic module loaded on the worktable; and
a second cutting unit, having a plurality of second cutters spaced apart from each other, that is disposed at the rear of the first cutting unit and cuts other parts of the photovoltaic module transported rearward without being cut by the first cutting unit.

2. The partial dismantling device of a photovoltaic module according to claim 1,
wherein the photovoltaic module has a back surface member facing a front surface member and a photovoltaic cell layer interposed between the front surface member and the back surface member, and
wherein the first cutting unit and the second cutting unit cut a sandwich including the photovoltaic cell layer and the back surface member.

3. The partial dismantling device of a photovoltaic module according to claim 1,
wherein the first transport unit has a pair of rollers disposed facing each other, a conveyor connected rotatably to the pair of rollers, and a support disposed between the pair of rollers so as to support the conveyor.

4. The partial dismantling device of a photovoltaic module according to claim 1,
wherein the first transport unit transports the photovoltaic module toward the first cutting unit, and
wherein the first cutting unit and the second cutting unit, in a state where positions are fixed, cut respective parts of the photovoltaic module approaching by the first transport unit.

5. The partial dismantling device of a photovoltaic module according to claim 1, further comprising:
a second transport unit that is disposed above the worktable so as to face the first transport unit and moves the photovoltaic module in the same direction as the first transport unit,
wherein the photovoltaic module passes between the first transport unit and the second transport unit in a state of being pressurized by the first transport unit and the second transport unit during a cutting process.

6. The partial dismantling device of a photovoltaic module according to claim 1,
wherein, before positions of the first cutting unit and the second cutting unit are fixed, heights of the first cutting unit and the second cutting unit or a height of the worktable is adjusted based on a location of the photovoltaic module loaded on the worktable.

7. The partial dismantling device of a photovoltaic module according to claim 1, further comprising:
a suction unit that suctions particles of the photovoltaic module cut by the first cutting unit and the second cutting unit.

8. The partial dismantling device of a photovoltaic module according to claim 1, further comprising:
a guide unit that is disposed in front of the first cutting unit and the second cutting unit with at least a part of the guide portion protruding toward a lower end of the first cutting unit or the second cutting unit, such that the photovoltaic module is inhibited from colliding with the first cutting unit and the second cutting unit during a relative movement with respect to the first cutting unit and the second cutting unit.

9. The partial dismantling device of a photovoltaic module according to claim 8,
wherein the guide unit is inclined toward the first cutting unit or the second cutting unit from a front side of the guide unit.

10. The partial dismantling device of a photovoltaic module according to claim 8,
wherein the guide unit has multiple fine holes through which a cooling fluid is sprayed toward the first cutting unit or the second cutting unit.

11. The partial dismantling device of a photovoltaic module according to claim 1,
wherein the first cutting unit and the second cutting unit have respective rotational axes which are perpendicular to a surface of the photovoltaic module.

12. The partial dismantling device of a photovoltaic module according to claim 1,
wherein the first cutting unit and the second cutting unit are spaced apart from each other by 15 mm or more.

13. A partial dismantling device of a photovoltaic module for dismantling the photovoltaic module having a front surface member, a back surface member facing the front surface member, and a photovoltaic cell layer interposed between the front surface member and the back surface member, the partial dismantling device comprising:
a worktable on which the photovoltaic module is loaded and which has a first transport unit that transports the loaded photovoltaic module;
a first cutting unit, having a plurality of first cutters spaced apart from each other, that cuts a part of the back surface member through a relative movement with respect to the photovoltaic module loaded on the worktable;
a second cutting unit, having a plurality of second cutters spaced apart from each other, that is disposed at the rear of the first cutting unit and cuts the other part of the back surface member transported rearward without being cut by the first cutting unit; and
a guide unit that is disposed in front of the first cutting unit and the second cutting unit with at least a part of the guide portion protruding toward a lower end of the first cutting unit or the second cutting unit, such that the photovoltaic module is inhibited from colliding with the first cutting unit and the second cutting unit during a relative movement with respect to the first cutting unit and the second cutting unit.
